(19) United States
(12) Patent Application Publication
(10) Pub. No.: US 2012/0097243 A1
(43) Pub. Date: Apr. 26, 2012

(54) DYE SENSITIZED SOLAR CELL WITH IMPROVED OPTICAL CHARACTERISTICS

(75) Inventor: Henrik Lindstrom, Uppsala (SE)

(73) Assignee: NLAB SOLAR AB, Stockholm (SE)

(21) Appl. No.: 13/379,624

(22) PCT Filed: Jul. 8, 2010
(86) PCT No.: PCT/EP10/59841

§ 371 Date: Dec. 20, 2011

Related U.S. Application Data
(60) Provisional application No. 61/224,277, filed on Jul. 9, 2009.

(51) Int. Cl. H01L 31/0352; H01L 31/18

(52) U.S. Cl. 136/256; 438/57; 257/E31.032

(57) ABSTRACT

The efficiency and the aesthetical properties are enhanced by spatial control of the P1DPC structural properties on the substrate surface area.

The spatial control of the P1DPC structural properties can be achieved through two principal routes:
1) selective spatial deposition of a plurality of P1DPCs on the substrate surface,
2) selective spatial manufacturing of P1DPCs with a non-planar surface structure, on the substrate surface.

### FIELD OF THE INVENTION

The invention concerns porous 1D photonic crystal (P1DPC) structures for controlling optical response of P1DPCs such that images based on P1DPCs can be created. Such images can be used to enhance efficiency and esthetical properties of Dye Sensitized Solar Cells (DSCs). The P1DPC based images are created by selective positioning of the deposited P1DPCs on the substrate surface area. The images can also be created by selectively varying the curvature of the P1DPCs on the substrate surface area. Variations in the images can also be accomplished by varying size, shape and optical response of the deposited P1DPCs.

### BACKGROUND OF THE INVENTION

The present invention relates to solar cells and in particular to dye-sensitized solar cells (DSCs), see e.g. U.S. Pat. No. 5,084,365. DSCs typically consist of a few micrometer thick porous TiO₂ electrode layer deposited onto a transparent conducting substrate (see FIG. 1). The conventional TiO₂ electrode layer also normally consists of interconnected TiO₂ metal oxide particles (anatase structure, typical average crystal size around 20 nm). The dyed TiO₂ electrode is formed by adsorbing dye molecules (typically a Ruthenium polypyridyl complex) onto the surface of the TiO₂ particles. The adsorption of dye-molecules is usually achieved by soaking the TiO₂ electrode in a solution of dye-molecules for several hours. The transparent conducting substrate 10a normally consists of a transparent conducting oxide (TCO), normally consisting of FTO or ITO, deposited onto a glass substrate 12. The dyed TiO₂ electrode 13 is in contact with an electrolyte (typically containing I⁻/I₃⁻ ion pairs) 14 and another transparent conducting substrate 10b and a glass substrate 12b i.e., a counter electrode 15, see FIG. 1. The TCO layer 10b of the counter electrode is usually covered with a thin catalytic layer of platinum (not indicated in FIG. 1).

Due to the low conductivity of the conducting substrate, the TiO₂ electrodes are typically deposited in segments with gaps in between in order to provide space for the deposition of current collectors between the TiO₂ electrode segments.

The edges of the conducting substrates are usually not deposited with TiO₂ electrode material. The two conducting substrates are usually sealed at the edges (using a hot melt such as Surlyn™ 1702) in order to protect the DSC components against the surrounding atmosphere and to prevent the evaporation or leakage of the electrolyte.

Sunlight is harvested by the dye producing photo-excited electrons that are injected into the conduction band of the nanocrystalline semiconductor network, and then into the conducting substrate. At the same time the redox electrolyte reduces the oxidized dye and transports the electron acceptors species (I₃⁻) to the counter-electrode. A record value of power conversion efficiency of 11% has been reported, although good quality cells typically provide between 5% and 8%.

Many efforts are directed towards improving the stability and the efficiency of the DSCs. Also the aesthetic qualities such as colour and semi-transparency of the DSC are important, making DSCs especially suitable for transparent window applications.

The most straightforward way of changing the visual appearance of DSCs is to use dyes of different colours, i.e., to manufacture e.g., a green, blue or red coloured DSC a green, blue or red dye is used, respectively. The drawback of this approach however, is that the efficiency of the DSC will depend strongly on the colour of the dye used since the light harvesting of a particular dye depends on the dye's absorption spectrum. Therefore the choice of DSC dye will determine both the efficiency and the colour appearance of the DSC.

By using photonic crystals it possible to produce DSCs with different colours without having to change the dye and without compromising efficiency. Spin coating has been used to produce such coloured DSCs (Colodrero, S., Adv. Mater. 2008, 20, 1-7).

One known way to increase the efficiency of DSCs is to increase the effective path of light in the TiO₂ electrode 13. This can be achieved by depositing a porous diffuse scattering layer 16 on top of the TiO₂ electrode 13, as shown in FIG. 2. The porous diffuse scattering layer 16 is normally several micrometers thick (e.g., 4 micrometers or thicker) and consists of large non-porous light scattering particles (typically several hundreds of nanometers in diameter). The light scattering particles 16 increase the effective path of light in the dyed TiO₂ electrode 13 by reflecting the light that is transmitted through the TiO₂ electrode back into the TiO₂ electrode again. The light scattering particles reflect light by diffuse reflection in a broad range of directions.

One problem with the use of a porous diffuse scattering layer consisting of several hundred nanometer sized non-porous particles is that it cannot easily be made semi-transparent. Consequently, DSCs containing this type of diffuse scattering layer is not suitable in windows and facade applications where semi-transparency is required.

Another problem is that the total TiO₂ layer thickness increases with the deposited light scattering layer leading to an increased ionic resistance in the electrolyte between the TiO₂ electrode and the counter electrode. An increased ionic resistance leads to an increased potential drop in the electrolyte lowering the fill factor in the solar cell performance.

Another problem with a thicker TiO₂ electrode is that the dye-sensitisation takes longer time when the layer thickness is larger because it takes longer time for the dye-molecules to penetrate the porous layer if the thickness of the porous layer is increased.

Another problem with the diffuse scattering layer is that the photocurrents generated by dye-molecules adsorbed onto these large particles are relatively small due to the small surface-to-volume ratio of large non-porous particles.

Another way to increase the effective path of the light is to deposit a porous 1D photonic crystal (P1DPC) on top of the light absorbing layer, as shown in FIG. 3. The P1DPC is coupled to the TiO₂ electrode 13 by depositing a porous multilayer 17 forming a structure of alternated particle layers of controlled thickness so that a periodic or quasi-periodic spacial modulation of the refractive index across the layers is achieved (Colodrero, S., Adv. Mater. 2008, 20, 1-7 and WO2008034932). By appropriate choice of the P1DPC lattice parameters, the P1DPC layer materials and the porosity of the layers within the P1DPC, the P1DPC can be designed to reflect light in certain useful wavelength regions and thereby increase the effective path of light in the dyed TiO₂ electrode in those wavelength regions. In order to reflect light efficiently (i.e., to achieve a strong reflectance peak) typically six or more alternated layers have to be deposited. In contrast to the diffuse light scattering layer consisting of large non-porous particles (see above), the deposited P1DPC reflects light by specular reflection (i.e., mirror-like reflection) in which light from a single incoming direction is reflected into a single outgoing direction.

The advantage with the P1DPC concept is that the reflecting layer is both transparent in certain wavelength regions and reflective in other wavelength regions at the same time and therefore such P1DPC layers can be used in solar cells for semi-transparent window applications. By depositing several P1DPCs with different lattice parameters, or different materials on top of each other, it is possible to reflect light selectively in several specific regions of the light spectrum thereby boosting the solar cell performance selectively in different spectral regions.

The application of photonic crystals in DSCs involves the deposition of several thin layers on top of the TiO₂ electrode.

The known method to deposit the P1DPC is to spin coat the P1DPC directly on top of the TiO₂ layer. In order to provide clean substrate areas between the deposited TiO₂ layer and on the edges of the substrate (i.e., the areas that are used for electrical connection- and sealing purposes), masks must be used in order to prevent coating the electric contact areas and/or sealing areas with P1DPC material.

### DESCRIPTION OF THE INVENTION

The invention concerns P1DPC structures for controlling optical response of deposited P1DPCs such that for example the efficiency and the esthetical properties of DSCs are enhanced. The efficiency and the aesthetical properties are enhanced by specific spatial control of the P1DPC structural properties on the substrate surface area.

The P1DPC structures are formed by the inhomogeneous spatial distribution of structural properties of the P1DPCs. The structural properties can be the distribution of P1DPCs on the substrate, P1DPC deposits, and three-dimensional formations of layers of P1DPC deposits; and P1DPC parameters, such as number of porous nanoparticle layers constituting the P1DPC, porosity, thickness or material of the porous nanoparticle layers.

The specific spatial control of the P1DPC structural properties are achieved through two principal routes:

1) selective spatial deposition of a plurality of P1DPCs on a substrate surface,
2) selective spatial manufacturing of P1DPCs with a non-planar surface structure, on the substrate surface.

The P1DPC structure is formed directly on the substrate surface and not in a separate step before deposition onto the substrate.

The DSC having P1DPC structures will have an increased efficiency. The selective optical response of patterns formed by the P1DPC structures makes it possible to enhance the esthetical properties of DSCs. A pattern can form visible images, but the pattern may only be discernable by microscope.

P1DPC structures can be formed by selective deposition of a plurality of P1DPC deposits onto a substrate surface. The optical response of such a plurality of deposited P1DPC deposits will depend on the periodic variation of the refractive index in the alternating single layers of each deposited P1DPC deposit and on the size and shape and location of the deposited p1DPC deposits on the substrate surface.

The optical response of the P1DPC will depend on the periodic variation of the refractive index in the alternating single layers. In the case of a P1DPC containing only one material, e.g., TiO₂, the periodic variation of the refractive index in the P1DPC can be achieved by varying the porosity of the alternated TiO₂ single layers creating a difference in the refractive index between the alternated TiO₂ single layers. The variation in refractive index can also be achieved by varying the materials in the alternating single layers, e.g., by using alternating single layers of TiO₂ and SiO₂. The optical response can be changed by changing the lattice parameter of the P1DPC as well. The lattice parameter is changed by varying the thicknesses of the deposited porous nanoparticle single layers.

The intensity of the reflected light from the deposited P1DPC can be controlled by varying the number of deposited porous alternated single layers, e.g., by increasing or reducing the number of deposited single layers the reflected light intensity can be increased or reduced, respectively.

The wavelength maximum of the reflected light from the deposited P1DPCs can be controlled by, e.g., varying the lattice parameter (by varying the thicknesses of the alternated single layers) whilst keeping the difference in refractive index constant.

The colour monochromaticity of the reflected light can be controlled by varying the difference in refractive index between the alternated layers, e.g., a higher monochromaticity can be achieved by choosing a smaller difference in refractive index.

By using a larger difference in refractive index of the alternated single layers, it is possible to get a stronger reflection and reduced monochromaticity i.e., a stronger reflection in a broader wavelength range can be achieved.

The selective spatial manufacturing of P1DPCs with a non-planar surface structure can be achieved by deforming a P1DPC layer by selectively applying pressure to the P1DPC layer or by selective deposition of P1DPC deposits onto a substrate with a preformed non-planar surface structure.

Depending on the shape of the P1DPC layer or P1PPC deposits the light reflection in certain directions can be suppressed and in other directions enhanced. By changing the curvature of the P1DPC surface structure at a specific location, it is possible to control the direction of the reflected light at this specific location. Thus the angle of the outgoing reflected light at a specific location on the P1DPC can be controlled by the curvature of the P1DPC surface.

Visual images can be created by variations in the curvature of the P1DPC surface. The variations in the curvature of the P1DPC layer or P1PDC deposits result in variations in reflected light from the P1DPCs. The variation of reflected light can be used to create images. For example a P1DPC layer or P1PDC deposits with both planar surface structure regions and wave-like surface structure regions can be made to appear mirror-like or glossy on planar surfaces and dark or matt on wave-like surfaces. Such visual optical effects can be exploited in order to create visual contrast and images.

The increase in efficiency of the DSCs is achieved by increasing the effective light path in the absorbing layer thereby increasing the absorption of light.

By manufacturing a wave-like P1DPC layer or P1PDC deposit on top of a conventional TiO₂ electrode layer in DSCs e.g., through P1DPC deposition onto a pre-shaped conventional TiO₂ layer or by deforming a P1DPC layer or P1PDC deposits deposited onto a conventional TiO₂ layer, the light reflection angle can be controlled such that the effective light path in the absorbing layer is increased. Other shapes than wave-like such as pyramidal shapes, conical shapes or zigzag shapes can be used depending on the intended application.

By manufacturing a P1DPC layer or P1PDC deposits having both planar and non-planar surface regions; it is possible to enhance both the glossiness and efficiency of the DSC in areas with higher specular reflectivity and to enhance both the efficiency and darkness or mattness of the DSC in the non-planar areas. The variation in optical response between glossy and dark/matt areas can be used for creating images or patterns on the DCS. Consequently, by manufacturing P1DPC layers or P1DPC deposits with varying spatial surface structure, it is possible to combine enhanced efficiency with enhanced aesthetical properties across the active area of the DSC.

By changing the surface structure of the P1DPC layer or P1DPC deposits it is possible to control the visual appearance as a function of viewing angle in terms of perceived colour and perceived reflected light intensity.

The invention is exemplified by a DSC, but the P1DPC structure can be used also for other applications such as security marking or security labelling, optical sensors for chemicals, or artistic purposes.

Thus, one aspect of the present invention relates to a dye sensitized solar cell (DSC) comprising a porous 1D photonic crystal (P1DPC) layer deposited on top of a substrate surface, characterised by that the P1DPC layer is a P1DPC structure formed by an inhomogeneous spatial distribution of structural properties of the P1PDCs.

Preferably, the P1PDC structure is formed by inhomogeneous distribution of P1DPC deposits on the substrate surface.

Advantageously, the P1PDC deposits can comprise P1PDCs with different optical responses. In such a case, the different optical responses can be formed by varying one or more P1PDC parameters, such as number of single nanoparticle layers constituting the P1DPC or nanoparticle layer porosity, nanoparticle layer thickness or nanoparticle layer material or difference in refractive index between alternated single layers of P1DPC.

In a possible embodiment of the invention, additional P1PDC deposits may be placed on top of one or more of the P1PDC deposits.

Advantageously, the P1PDC deposits and possible additional P1PDC deposits are embedded in a matrix of nanoparticles. In such a case, an additional layer of large non-porous light scattering particles can be placed on top of the embedded P1DPC deposits.

According to a possible embodiment of the invention, at least a part of the substrate surface is non-planar.

In a DSC in accordance with the invention, the substrate may comprise a transparent conductive oxide. For example the substrate comprises a porous TiO2, porous ZnO, a porous Nb2O5 or a porous SnO2 electrode layer, preferably a porous TiO2 electrode layer.

Advantageously, an additional layer of large non-porous light scattering particles are placed on top the P1PDC deposits and possible additional P1PDC deposits.

Another aspect of the present invention relates to a method for producing a DSC comprising a P1PDC deposit, in particular a DSC comprising a P1PDC deposit in which at least a part of the substrate surface is non-planar, wherein the substrate surface and P1PDC deposit are deformed by a tool applying pressure selectively.

A DSC comprising a P1PDC deposit in which at least a part of the substrate surface is non-planar, can also be obtained with a method wherein the P1PDC deposit is deposited onto a pre-formed non-planar substrate.

A further aspect of the present invention relates to a conducting substrate comprising spots of different optical responses over the substrate surface, in which the spots are formed by P1DPC deposits.

Preferably, a conducting substrate according to the invention has a partly non-planar surface with a P1DPC deposit layer covering the conducting substrate and thereby having both planar surface structure regions and non-planar surface structure regions that can be made to appear mirror-like or glossy on the planar surface regions and dark or matt on non-planar surfaces regions.

A conducting substrate comprising a P1PDC structure can be part of a security label, an optical sensor for chemicals, or an esthetical surface.

### LIST OF DRAWINGS

FIG. 1 shows a schematic cross-sectional picture of a dye-sensitized solar cell.

FIG. 2 shows a schematic cross-sectional picture of a dye-sensitized solar cell with a diffuse scattering layer deposited on top of the TiO₂ electrode.

FIG. 3 shows a schematic cross-sectional picture of a dye-sensitized solar cell with a photonic crystal deposited on top of the TiO₂ electrode. The black lines and white spaces between the lines represent the alternated particle layer structure constituting the P1DPC.

FIG. 4 shows a selective deposition of a P1DPC of TiO₂ onto a conducting substrate.

FIG. 5 shows a selective deposition of P1DPCs onto a substrate. Several lattice parameters are used. Tandem structures consisting of two different P1DPCs deposited on top of each other are used.

FIG. 6 shows a selectively deposited P1DPCs embedded in a matrix of nanoparticles.

FIG. 7 shows P1DPCs deposited on top of the conventional TiO₂ layer.

FIGS. 8A and 8B show mechanical deformation of a P1DPC layer deposited onto a substrate.

FIGS. 9A and 9B show multilayer deposition of a P1DPC on pre-shaped substrate surface.

FIG. 10 shows conventional TiO₂ layer deposited onto a selectively structured P1DPC layer.

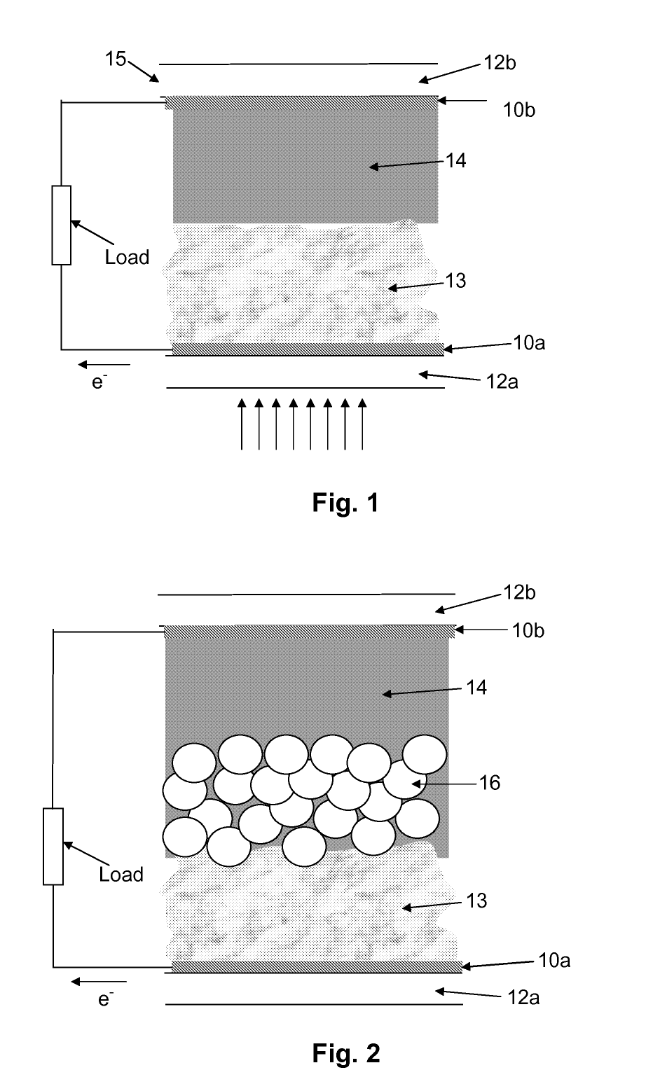

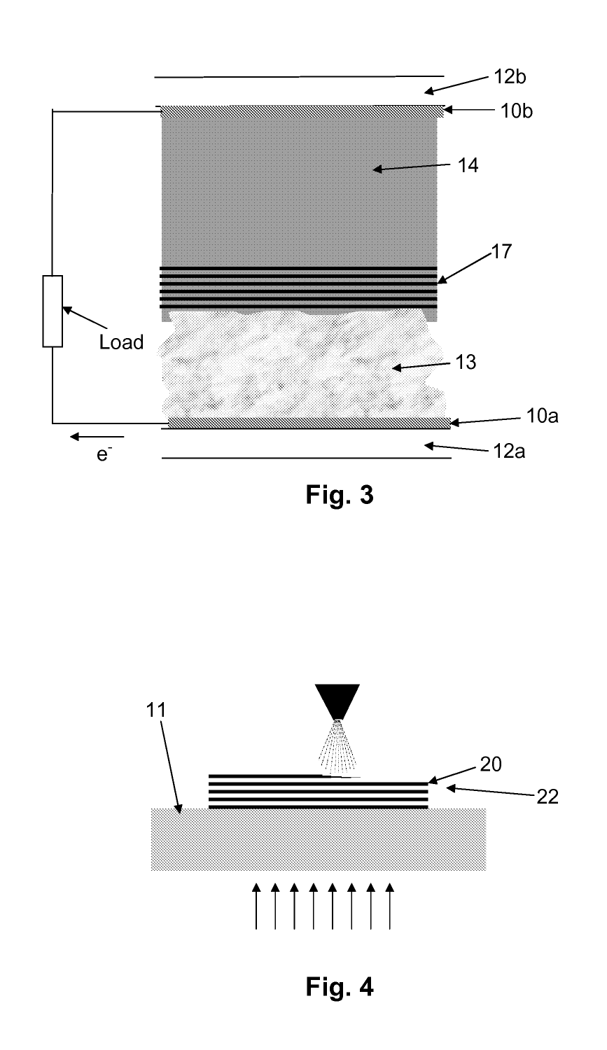

### DETAILED DESCRIPTION OF THE INVENTION

The invention is further explained by reference to the figures. The invention is however not restricted to the embodiments shown by the figures.

FIG. 4 shows deposition of a single P1DPC layer 20 onto a conducting substrate 11 for forming a P1DPC layer 22. Alternating layers 20 with different refractive indexes are deposited on top of each other. The black lines and the white spaces between the black lines represent the alternated porous layers of nanoparticles creating a periodic variation of the refractive index in the P1DPC.

The optical response of the P1DPC will depend on the periodic variation of the refractive index in the alternating layers. In the case of a P1DPC containing only one type of material, e.g., TiO₂, the periodic variation of the refractive index in the P1DPC can be achieved by varying the porosity of the alternated TiO₂ layers creating a difference in the refractive index between the alternated TiO₂ layers. The variation in refractive index can also be achieved by varying the type of materials in the alternating layers, e.g., by using alternating layers of TiO₂ and SiO₂. The optical response can be changed by changing the lattice parameter of the P1DPC as well. The lattice parameter is changed by varying the thicknesses of the deposited porous nanoparticle layers.

The intensity of the reflected light from the deposited P1DPC can be controlled by varying the number of deposited porous alternated layers, e.g., by increasing or reducing the number of deposited layers the reflected light intensity can be increased or reduced, respectively.

The wavelength maximum of the reflected light from the deposited P1DPCs can be controlled by, e.g., varying the lattice parameter (by varying the thicknesses of the alternated layers) whilst keeping the difference in refractive index constant.

The colour monochromaticity of the reflected light can be controlled by varying the difference in refractive index between the alternated layers, e.g., a higher monochromaticity can be achieved by choosing a smaller difference in refractive index.

By using a larger difference in refractive index of the alternated layers, it is possible to get a stronger reflection and reduced monochromaticity i.e., a stronger reflection in a broader wavelength range can be achieved.

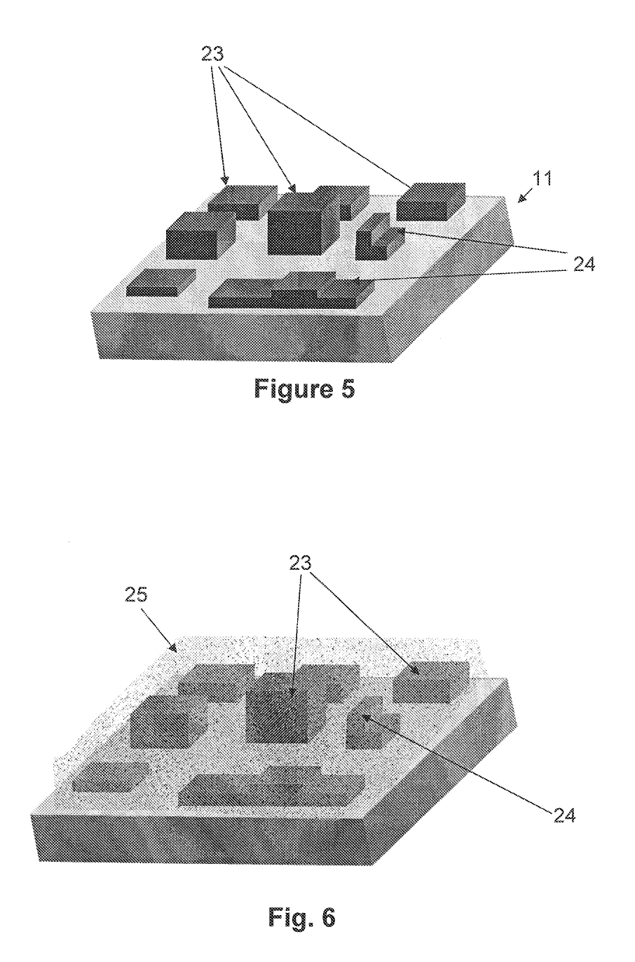

By depositing the P1PDCs inhomogeneously over the substrate surface patterns are formed. FIG. 5 shows a pattern having several structurally different P1DPC deposits 23 on a substrate 11.

It is possible to create a multicolour pattern, based on the variation of the reflection of light from the different deposited P1DPCs. Each P1DPC deposit will reflect light and the intensity of the light reflection and the reflected wavelength maximum (i.e, the perceived light intensity and the perceived reflected colour, respectively) and the wavelength range (i.e., monochromaticity) of the reflected light can be controlled by varying the structural P1DPC properties as a function of their position. Consequently a substrate with a multicolour pattern can be produced.

Furthermore, it is possible to deposit additional P1DPC deposits on top of each other creating tandem P1DPC structures 24, see FIG. 5. Tandem structures allow for even greater flexibility in terms of control over the optical response. For example, tandem structures consisting of two layers of P1DPC deposits allow for light of two different wavelength ranges (corresponding to the reflection from two different P1DPCs) to be reflected from the same location on the substrate. Consequently, by using tandem structures, a mixture of two different reflected colours can be produced.

The difference in index of refraction between the materials in the P1DPC deposits and the index of refraction of their environment (e.g., air) can be changed by embedding the P1DPCs in nanoparticles of e.g., a conventional TiO₂ layer. FIG. 6 shows a pattern of P1PDC deposits 23, 24 embedded in a matrix of nanoparticles 25. By embedding the pattern in a matrix of nanoparticles the light scattering effect of the P1DPC deposits can be reduced.

It is also possible to deposit an additional layer of large non-porous light scattering particles on top of the embedded P1DPC deposits (the non-porous scattering layer is not shown in FIG. 6). Such a light scattering layer can be used for manufacturing non-semi-transparent (i.e., opaque) DSCs having both improved efficiency and improved aesthetical properties and which can be used for creating images on non-semi-transparent DSCs.

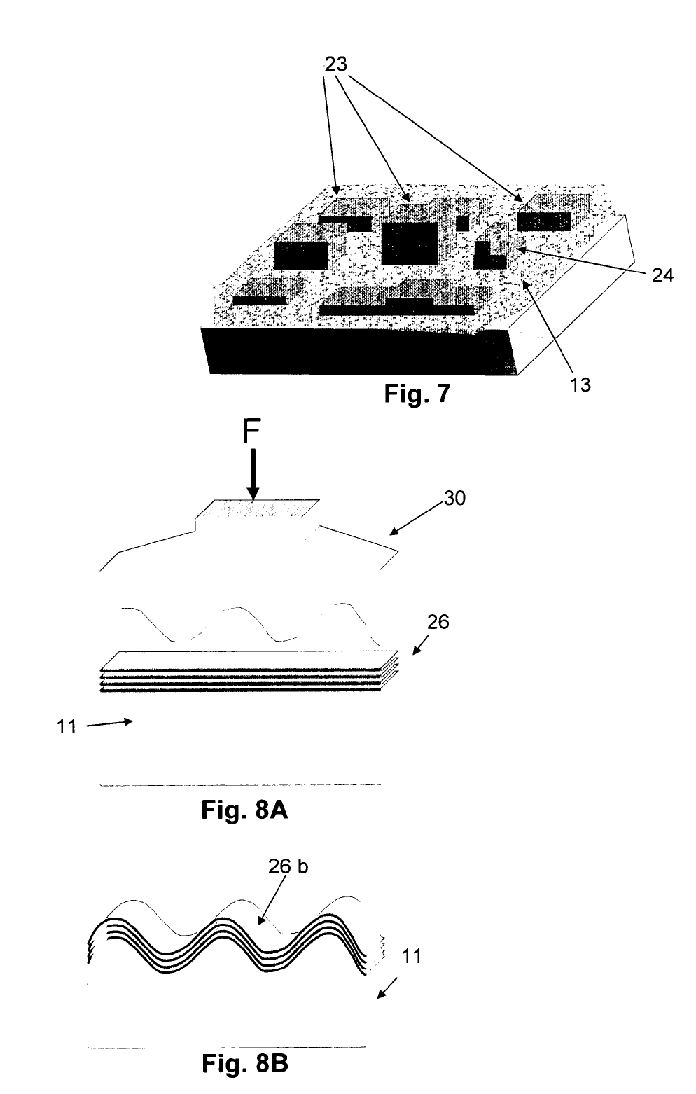

It is also possible to selectively deposit the P1DPC deposits 23, 24 on top of a conventional TiO₂ electrode layer 13, see FIG. 7. This can be useful for improving efficiency and for creating images on semi-transparent DSCs.

It is also possible to deposit a scattering layer consisting of large non-porous light scattering particles on top of the P1DPC deposits 23, 24 in FIG. 7 (the scattering layer is not shown in FIG. 7). This could be useful for improving the efficiency and for creating images in non-semi-transparent (i.e., opaque) DSCs.

By depositing P1DPC deposits, on spots of the conducting substrate surface, with different optical responses at different spatial positions on the substrate it is possible to create multicolour images. The images could be created by differences in reflected light intensity and differences in reflected wavelengths at different positions on the substrate surface.

So far only flat, planar substrates with P1DPC deposits have been described. However, the optical response of the P1DPC structure can be changed by changing the surface structure on which the P1DPCs are deposited.

The surface structure of a P1DPC deposit layer can be changed by deforming the P1DPC deposit layer by applying pressure selectively to the P1DPC layer and the underlying substrate, see FIGS. 8A and 8B. In FIG. 8A, a patterned mechanical pressing tool 30 is pressed against a planar P1DPC deposit or layer 26 deposited on a substrate 11 in order to shape or engrave the P1DPC deposit or layer 26 and the substrate 11 so that a non-planar surface structure of the P1DPC deposit or layer 26b on the substrate 11 is achieved (see FIG. 8B).

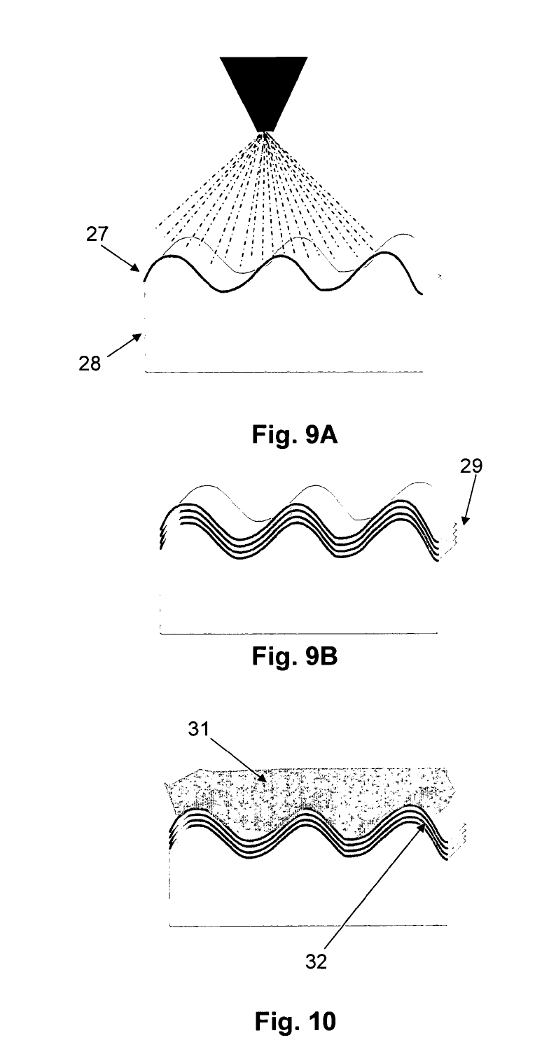

Another way of changing the surface structure of the P1DPC layer is to deposit each P1DPC single layer 27 onto a pre-shaped non-planar substrate 28, see FIGS. 9A and 9B, such that that the shape of P1DPC deposit 29 follow the shape of the underlying substrate.

The optical response of the P1DPC deposits with non-planar surface structure will depend on the detailed geometry and shape of the P1DPC structure. In FIGS. 8B and 9B a wave-like surface structure of the P1DPC deposit and substrate are shown. Such a surface structure can be useful for controlling the direction of the light that is reflected on the P1DPC deposits.

Depending on the shape of the P1DPC deposit the light reflection in certain directions can be suppressed and in other directions enhanced. By changing the curvature of the P1DPC deposit surface at a specific location, it is possible to control the direction of the reflected light at this specific location. Thus the angle of the outgoing reflected light at a specific location on the P1DPC deposit can be controlled by changing the curvature of the P1DPC deposit surface.

Visual images can be created by creating variations in the curvature of the P1DPC layer. The variations in the curvature of the P1DPC layer will create variations in reflected light from such P1DPCs layers. The variation of reflected light can be used to create images. For example a P1DPC layer with both planar surface structure regions and wave-like surface structure regions can be made to appear mirror-like or glossy on planar surfaces and dark or matt on wave-like surfaces. Such visual optical effects can be exploited in order to create visual contrast and images.

A strategy to increase the efficiency of DSCs is to increase the effective light path in the absorbing layer thereby increasing the absorption of light. By manufacturing a wave-like P1DPC deposit on top of a conventional TiO₂ electrode layer in DSCs (e.g., through P1DPC deposition onto a pre-shaped conventional TiO₂ electrode layer or by deforming a P1DPC deposit deposited onto a conventional TiO₂ layer), the light reflection angle can be controlled such that the effective light path in the absorbing layer is increased. Of course other shapes such as pyramidal shapes or conical shapes or zigzag shapes can be used as well, to suit the application at hand.

By manufacturing a P1DPC layer having both planar and non-planar surface regions; it is possible to enhance both the glossiness and efficiency of the DSC in areas with higher specular reflectivity and to enhance both the efficiency and darkness or mattness of the DSC in the non-planar areas. The variation in optical response between glossy and dark/matt areas can be used for creating images on the DCS. Consequently, by manufacturing P1DPC layers with varying spatial surface structure, it is possible to combine enhanced efficiency with enhanced aesthetical properties across the active area of the DSC.

Different viewing angles on the planar P1DPC layer normally result in different visual appearances in terms of perceived colour and perceived reflected light intensity. Consequently by changing the surface structure of the P1DPC layer it is possible to control the visual appearance as a function of viewing angle in terms of perceived colour and perceived reflected light intensity on the P1DPC layer.

It is possible to deposit a conventional TiO₂ electrode layer 31 on top of the surface structured P1DPC deposit 32, see FIG. 10. This could be useful to reduce the difference in refractive index between the P1DPC layer and the environment in order to reduce light scattering effects of the P1DPC deposit.

It is also possible to deposit a layer consisting of large non-porous light scattering particles on top of the conventional TiO₂ layer in FIG. 10 (the scattering layer is not shown in FIG. 10. This could be useful for improving the efficiency and for creating images in non-semi-transparent (i.e., opaque) DSCs.

Deposition of P1DPC single layers comprises a first step of preparing suspensions of nanoparticles. The particles can be made of e.g., SiO₂, TiO₂, SnO₂, Al₂O₃, MgO, ZnO, Nb₂O₅, CeO₂, V₂O₅, HfO₂, CO₃O₄, NiO, Al₂O₃, In₂O₃, Sb₂O₃. The sizes of the particles can be in the range of 1-100 nm. The concentration of nanoparticles can be between 0.1% and 70% (solid volume/total volume ratio). The nanoparticles can be produced by any technique known in the art of nanoparticle production. The nanoparticles can be in the form of powders or colloidal suspensions or powder suspensions.

A useful suspension of the nanoparticle powder can be produced using conventional techniques such as bead milling and sonication. The nanoparticle suspension formulation includes adequate solvents, binders or, additives etc depending on the application. The nanoparticle suspension formulation depends on the application at hand. Examples of solvents are water or alcohols etc. Examples of binders are PEG 20,000, PMMA, polystyrene, Carbowax™ or ethyl cellulose, methyl cellulose etc. Examples of additives are dispersion additives, levelling agents, deforming agents, anti-cratering agents, waxes etc.

The patterned P1DPC deposits comprising a plurality of different P1DPC single layers can be produced by depositing the nanoparticle suspensions on substrates using well known printing techniques such as: ink-jet, screen printing, flexographic printing, gravure printing, embossed printing, etc. It is preferred to use printing techniques capable of producing thin layers of sub-micrometer and micrometer thickness. In the case of printing a plurality of different P1DPC single layers it is preferred to use printing techniques capable of producing a patterned deposition without the need for masking the substrate. It is also preferred to use printing methods that allow several layers to be deposited onto each other with adequate alignment and registration of the deposited layers.

The deposits of alternated layers can be formed by alternate deposition of single layers of controlled thickness so that a periodic or quasiperiodic spatial modulation of the refractive index is attained across the deposit.

The P1DPC deposits having a continuous homogeneous P1DPC layer of the same thickness can be produced by depositing the nanoparticle suspensions on substrates using well known printing techniques such as: spraying (e.g., ultrasonic spraying), dip-coating, spin-coating, ink-jet, screen printing, flexographic printing, gravure printing, embossed printing, etc. It is preferred to use printing techniques capable of producing thin layers of sub-micrometer and micrometer thickness. It is also preferred to use printing methods that allow several single layers to be deposited onto each other with adequate alignment and registration of the deposited layers.

The deposit consisting of alternated layers can be formed by alternate deposition of single layers of controlled thickness so that a periodic or quasiperiodic spatial modulation of the refractive index is attained across the deposited multilayer.

After printing the first nanoparticle suspension single layer the solvent is allowed to evaporate. The deposited layer can then be subjected to a brief heat treatment to assure that most of the solvent is evaporated. The next nanoparticle suspension single layer is then printed on top of the first dried nanoparticle suspension single layer and the solvent is allowed to evaporate again possibly including a heating step if necessary and so forth. Several additional single layers can be deposited on top of each other until sufficiently many layers have been printed on top of each other to yield the desired optical properties.

Composites of polymer with nanoparticles, exhibiting 1D photonic crystal properties, have been manufactured using UV curable polymers containing nanoparticles combined with photo initiators. Such UV-curable polymer-nanoparticle systems are suitable for flexographic printing purposes.

The substrate can be a transparent conducting substrate such as conducting glass (e.g., a soda lime glass sheet equipped with a TCO layer (e.g., of fluorine doped SnO2) or conducting plastic (e.g., a PET sheet equipped with an ITO layer). In the case the P1DPC single layers are deposited directly onto a conducting substrate it is preferred to use P1DPC of TiO₂. The substrate could also be the conventional porous TiO₂ layer or a porous ZnO layer or a porous Nb₂O₅ layer or a porous SnO₂ layer deposited onto a transparent conducting glass. The substrate surface could be smooth or pre-shaped. It is preferred that the pore size of porous substrates is smaller or comparable to the nanoparticle sizes in the nanoparticle layers in the P1DPC.

The P1DPC layers can be deformed by selectively applying pressure to the deposited P1DPC layer. Selective pressure can be applied mechanically using a patterned surface such as an engraved metal or engraved ceramic. When sufficient pressure is applied the pattern from the engraved surface can be transferred to the P1DPC layer creating a variation in the surface structure of the P1DPC layer. The deformation technique is especially suitable in the case the P1DPC layer is deposited onto a soft substrate such as plastic or a highly porous metal oxide layer (e.g., the conventional TiO₂ layer). Rigid substrates such as glass are less suitable for the deformation technique in cases where the P1DPC layers are deposited directly on top of the conducting substrate. It is preferred to use non-sticking engraved tools for creating surface structures in the P1DPC layers. The deformation technique can be combined with heating, e.g., in cases where deformable conducting substrates such as plastic substrates are used.

In the examples above it can be advantageous that the deposited P1DPC single layers are heated at some stage in order to remove combustible components and to sinter the layers of nanoparticles inside the P1DPC together in order to create a mechanically stable P1DPC structure.

After the deposition of the P1DPC deposits has been carried out, standard procedures can be used to manufacture the DSC including dye-sensitization, electrolyte filling and device sealing.

1. A dye sensitized solar cell (DSC) comprising a porous 1D photonic crystal (P1DPC) layer deposited on top of a substrate surface, characterised by that the P1DPC layer is a P1DPC structure formed by an inhomogeneous spatial distribution of structural properties of the P1PDCs.

2. A DSC in accordance with claim 1, wherein the P1PDC structure is formed by inhomogeneous distribution of P1DPC deposits on the substrate surface.

3. A DSC in accordance with claim 2, wherein the P1PDC deposits comprise P1PDCs with different optical responses.

4. A DSC in accordance with claim 3, wherein the different optical responses are formed by varying one or more P1PDC parameters, such as number of single nanoparticle layers constituting the P1DPC or nanoparticle layer porosity, nanoparticle layer thickness or nanoparticle layer material or difference in refractive index between alternated single layers of P1DPC.

5. A DSC in accordance with claim 2, wherein additional P1PDC deposits may be placed on top of one or more of the P1PDC deposits.

6. A DSC in accordance with claim 2, wherein the P1PDC deposits and possible additional P1PDC deposits are embedded in a matrix of nanoparticles.

7. A DSC in accordance with claim 6, wherein an additional layer of large non-porous light scattering particles are placed on top of the embedded P1DPC deposits.

8. A DSC in accordance with claim 1, wherein at least a part of the substrate surface is non-planar.

9. A DSC in accordance with claim 1, wherein the substrate comprises a transparent conductive oxide.

10. A DSC in accordance with claim 1, wherein the substrate comprises a porous TiO₂, porous ZnO, a porous Nb₂O₅ or a porous SnO₂ electrode layer.

11. A DSC in accordance with claim 10, wherein the substrate comprises a porous TiO₂ electrode layer.

12. A DSC in accordance with claim 10, wherein an additional layer of large non-porous light scattering particles are placed on top the P1PDC deposits and possible additional P1PDC deposits.

13. A method for producing a DSC comprising a P1PDC deposit in accordance with claim 8, wherein the substrate surface and P1PDC deposit are deformed by a tool applying pressure selectively.

14. A method for producing a DSC comprising a P1PDC deposit in accordance with claim 8, wherein the P1PDC deposit is deposited onto a pre-formed non-planar substrate.

15. A conducting substrate comprising spots of different optical responses over the substrate surface, wherein the spots are formed by P1DPC deposits.

16. A conducting substrate having a partly non-planar surface, comprising a P1DPC deposit layer covering the conducting substrate and thereby having both planar surface structure regions and non-planar surface structure regions and appearing mirror-like or glossy on the planar surface regions and dark or matt on non-planar surfaces regions.

17. A conducting substrate, wherein the substrate comprises a P1PDC structure and is part of in a security label, an optical sensor for chemicals, or an esthetical surface.

18. A DSC in accordance with claim 3, wherein additional P1PDC deposits may be placed on top of one or more of the P1PDC deposits.

19. A DSC in accordance with claim 4, wherein additional P1PDC deposits may be placed on top of one or more of the P1PDC deposits.

20. A DSC in accordance with claim 3, wherein the P1PDC deposits and possible additional P1PDC deposits are embedded in a matrix of nanoparticles.
